(19) United States
(12) Patent Application Publication
(10) Pub. No.: US 2009/0050052 A1
(43) Pub. Date: Feb. 26, 2009

(54) PLASMA PROCESSING APPARATUS

(75) Inventors: Caizhong Tian, Tokyo (JP); Toshihisa Nozawa, Tokyo (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/278,420

(22) PCT Filed: Jan. 26, 2007
(86) PCT No.: PCT/JP2007/051294

§ 371 Date: Aug. 6, 2008

(30) Foreign Application Priority Data
Feb. 7, 2006 (JP) 2006-030234

(51) Int. Cl. C23C 14/28

(52) U.S. Cl. 118/50.1

(57) ABSTRACT

Provided is a plasma processing apparatus capable of preventing an unnecessary adhesion film from being deposited in a processing chamber using plasma. The plasma processing apparatus 32 includes a processing chamber 34 having an opened ceiling portion 54a and capable of being evacuated to a vacuum therein; a ceiling plate 54 airtightly installed at the ceiling portion 54a and made of a microwave-transmissive dielectric material; a planar antenna member 58 installed on the ceiling plate 54, for introducing a microwave into the processing chamber; and a gas introduction mechanism 44. A film deposition preventing member 78 made of a dielectric material and elongated from the ceiling plate 54 is installed to correspond to a portion where an unnecessary adhesion film is likely to be deposited within the processing chamber 34. The film deposition preventing member 78 is configured as a rod-shaped member 104.

### TECHNICAL FIELD

The present disclosure relates to a plasma processing apparatus for use in processing a semiconductor wafer or the like by allowing plasma generated by microwaves to act on the wafer.

### BACKGROUND ART

Along with a recent trend of high densification and high miniaturization of semiconductor products, a plasma processing apparatus has been used for performing film formation, etching, ashing and the like in a semiconductor manufacturing process. Specifically, since plasma can be generated stably even under a high vacuum condition at a relatively low pressure in the range of, e.g., about 0.1 mTorr (13.3 mPa) to several Torr (several hundreds of Pa), a microwave plasma apparatus for generating a high-density plasma by using microwaves tends to be used.

Such plasma processing apparatus is disclosed in Patent Documents 1 to 4 or the like. Herein, a typical plasma processing apparatus using microwaves will be described schematically with reference to FIG. 12. FIG. 12 presents a schematic configuration diagram illustrating a typical plasma processing apparatus in accordance with the prior art.

As illustrated in FIG. 12, a plasma processing apparatus 2 includes an evacuable processing chamber 4 and a mounting table 6 disposed in the processing chamber 4 for mounting a semiconductor wafer W thereon. Further, airtightly provided in a ceiling portion facing the mounting table 6 is a disc-shaped ceiling plate 8 made of a microwave transmissive material such as aluminum nitride, quartz, or the like. Further, provided in a sidewall of the processing chamber 4 are a nozzle 10 for introducing a gas into the processing chamber 4 and a loading/unloading opening 12 for a wafer W. A gate valve G for airtightly opening and closing the opening 12 is installed at the opening 12. Further, a gas exhaust port 14 is provided in a bottom portion of the processing chamber 4 and connected to a vacuum exhaust system (not shown). With this configuration, the inside of the processing chamber 4 can be evacuated to vacuum as mentioned above.

Furthermore, provided on or above the top surface of the ceiling plate 8 are a disc-shaped planar antenna member 16 made of, e.g., a copper plate having a thickness of several mm and a slow-wave member 18 made of, e.g., a dielectric material, for shortening a wavelength of the microwave in the radial direction of the planar antenna member 16. The planar antenna member 16 is provided with a plurality of microwave radiation holes 20 formed of through holes having, for example, an elongated groove shape. The microwave radiation holes 20 are arranged generally in a concentric or spiral pattern. Additionally, a central conductor 24 of a coaxial waveguide 22 is connected to a central portion of the planar antenna member 16, so that microwaves of, e.g., 2.45 GHz, generated by a microwave generator 26 can be guided to the planar antenna member 16 after being converted to a predetermined oscillation mode by a mode converter 28. With this configuration, while propagating the microwaves along a radial direction of the antenna member 16 in a radial shape, the microwaves are emitted through the microwave radiation holes 20 provided in the planar antenna member 16, and are transmitted through the ceiling plate 8 to be finally introduced into the processing chamber 4. By the microwaves, plasma P is generated in a processing space S of the processing chamber 4, so that a plasma process such as an etching, a film formation or the like can be performed on the semiconductor wafer W.

To be more specific, since the microwaves radiated from the planar antenna member 16 are introduced into the processing space S through the ceiling plate 8, a high-density plasma is inevitably generated in the processing space S above the wafer W. During film formation, for example, active species or a dissociated gas generated by the plasma P reacts with the wafer W, so that the film formation is carried out on the wafer W. During etching, for example, a surface of the wafer is etched by the energy of the active species generated by the plasma.

Patent Document 1: Japanese Patent Laid-open Publication No. H3-191073
Patent Document 2: Japanese Patent Laid-open Publication No. H5-343334
Patent Document 3: Japanese Patent Laid-open Publication No. H9-181052

### Patent Document 4: Japanese Patent Laid-open Publication No. 2003-332326

However, while the above-mentioned various processes are being performed, the atmosphere inside the processing chamber 8 is continuously exhausted through the gas exhaust port 14 by vacuum evacuation. The atmosphere under the exhaustion contains some residues of the active species or dissociated gas components, and thus, the residual active species or dissociated gas components, or, in case of etching, gas components generated from a wafer surface are concentrated around the gas exhaust port 14. Also, since the gas exhaust port 14 is located away from the plasma P region, energy is not supplied thereto, so that the residual active species or dissociated gas components are deactivated and thus they are returned to their original state. As a result, an unnecessary adhesion film X, which may cause particle generation or clogging of the gas exhaust port 14, is deposited around the gas exhaust port 14.

The place where the unnecessary adhesion film X is highly likely to be deposited is not limited to around the gas exhaust port 14, but various other places are also possible depending on the kind of plasma processing. For example, the unnecessary adhesion film X may be deposited at a low-temperature portion distanced away from the plasma P region, for example, on the entire inner wall surface of the processing chamber 4. In particular, the unnecessary adhesion film may be deposited around the loading/unloading opening 12 which is used for loading and unloading the wafer W and tends to be at a lower temperature level than other portions. The above-mentioned problem has been observed not only during the plasma film formation process or the plasma etching process but also in various plasma processes such as a plasma nitridation process or a plasma oxidation process.

### DISCLOSURE OF THE INVENTION

In view of the foregoing, the present disclosure provides a plasma processing apparatus capable of preventing deposition of an unnecessary adhesion film in a plasma processing chamber.

In accordance with one aspect of the present invention, there is provided a plasma processing apparatus including: a processing chamber having an opened ceiling portion, a sidewall and a bottom portion, and capable of being evacuated to a vacuum therein; a mounting table installed in the processing chamber, for mounting thereon a target object to be processed; a ceiling plate airtightly installed at the ceiling portion and made of a microwave-transmissive dielectric material; a planar antenna member installed on a top surface of the ceiling plate, for introducing a microwave into the processing chamber; a microwave supply mechanism for supplying the microwave to the planar antenna member; and a gas introduction mechanism for introducing a necessary processing gas into the processing chamber, wherein a film deposition preventing member made of a dielectric material and elongated from the ceiling plate is installed to correspond to a portion where an unnecessary adhesion film is likely to be deposited within the processing chamber.

As described, since the film deposition preventing member made of the dielectric material and elongated downward from the ceiling plate is provided to correspond to the portion in the processing chamber where the unnecessary adhesion film is likely to be deposited, the microwave transmitted through the ceiling plate are also propagated to the film deposition preventing member. As a result, since plasma is generated around the film deposition preventing member, residues of active species or dissociated gases contained in the atmosphere are supplied with energy from the plasma generated around the film deposition preventing member, so that deposition of an unnecessary adhesion film can be prevented.

The sidewall or the bottom portion of the processing chamber is provided with a gas exhaust port, and the portion where the unnecessary adhesion film is likely to be deposited is the vicinity of the gas exhaust port of the processing chamber, and the film deposition preventing member is configured as a rod-shaped member formed in a rod shape.

In this configuration, it is possible to prevent deposition of the unnecessary adhesion film in the processing chamber or around the gas exhaust port formed in the sidewall of the processing chamber.

A distance between a lower end portion of the rod-shaped member and the gas exhaust port is not greater than about 100 mm.

The rod-shaped member is formed in a columnar shape and a radius r of the rod-shaped member of the columnar shape satisfies a formula of r≧λ/3.41 (λ represents a wavelength of a microwave in the dielectric material constituting the rod-shaped member).

The rod-shaped member has a cross section formed in a rectangular shape and a length a of a longer side of the rectangular cross section satisfies a formula of a≧λ/2 (λ represents a wavelength of a microwave in the dielectric material constituting the rod-shaped member).

The portion where the unnecessary adhesion film is likely to be deposited is the sidewall of the processing chamber, and the film deposition preventing member is formed to conform to the shape of the sidewall.

An opening for loading and unloading the target object is provided in the sidewall of the processing chamber, and the portion where the unnecessary adhesion film is likely to be deposited is the opening for loading and unloading the target object formed in the processing chamber.

In this configuration, it is possible to prevent deposition of the unnecessary adhesion film around the loading/unloading opening for the target object.

The film deposition preventing member is configured as a plurality of rod-shaped members arranged along the sidewall while spaced apart from the sidewall by a predetermined interval.

The film deposition preventing member is configured as a plate-shaped member formed along the sidewall of the processing chamber.

The plate-shaped member has a cross section formed in a circular arc shape.

The film deposition preventing member is configured as a cylindrical member formed along the sidewall of the processing chamber.

A distance between the film deposition preventing member and the sidewall of the processing chamber is not greater than about 100 mm.

The rod-shaped member is formed in a columnar shape and a radius r of the rod-shaped member of the columnar shape satisfies a formula of r≧λ/3.41 (λ represents a wavelength of a microwave in the dielectric material constituting the rod-shaped member).

The rod-shaped member has a cross section formed in a rectangular shape and a length a of a longer side of the rectangular cross section satisfies a formula of a≧λ/2 (λ represents a wavelength of a microwave in the dielectric material constituting the rod-shaped member).

In accordance with the plasma processing apparatus described in the present disclosure, effects as follows can be obtained.

Since the film deposition preventing member made of the dielectric material and elongated from the ceiling plate is installed at the portion corresponding to where the unnecessary adhesion film is likely to be deposited within the processing chamber, the microwave transmitted through the ceiling plate is also propagated to the film deposition preventing member. As a result, since the plasma is generated around the film deposition preventing member, residues of active species or dissociated gases contained in the atmosphere are supplied with energy from the plasma generated around the film deposition preventing member, so that deposition of the unnecessary adhesion film can be prevented.

In particular, in accordance with the present disclosure, it is possible to prevent deposition of the unnecessary adhesion film in the processing chamber or around the gas exhaust port of the processing chamber.

Further, in accordance with the present disclosure, it is also possible to prevent deposition of the unnecessary adhesion film around the loading/unloading opening for the target object.

### BRIEF DESCRIPTION OF THE DRAWINGS

FIG. 1 provides a configuration view of a plasma processing apparatus in accordance with a first embodiment of the present invention;

FIG. 2 provides a perspective view of a ceiling plate and a film deposition preventing member;

FIG. 3 represents a schematic view illustrating a plasma generation state within a processing chamber;

FIGS. 4A and 4B present photographs showing simulation results of the first embodiment of the present invention using a rod-shaped (columnar) film deposition preventing member having a circular cross section;

FIG. 5 shows a perspective view of a ceiling plate and a film deposition preventing member used in a plasma processing apparatus in accordance with a second embodiment of the present invention;

FIG. 6 illustrates a schematic configuration view of a plasma processing apparatus in accordance with a third embodiment of the present invention;

FIG. 7 provides a cross sectional view taken in the direction of the arrows along the line A-A in FIG. 6;

FIG. 8 shows a perspective view showing a ceiling plate and a film deposition preventing member used in a plasma processing apparatus in accordance with a fourth embodiment of the present invention;

FIG. 9 illustrates a schematic configuration view of a plasma processing apparatus in accordance with a fifth embodiment of the present invention;

FIG. 10 illustrates a perspective view showing a ceiling plate and a film deposition preventing member used in a plasma processing apparatus in accordance with the fifth embodiment of the present invention;

FIG. 11 provides a bottom view of a ceiling plate and a film deposition preventing member used in a plasma processing apparatus in accordance with a sixth embodiment of the present invention; and

FIG. 12 illustrates a schematic configuration view of a general prior-art plasma processing apparatus.

### BEST MODE FOR CARRYING OUT THE INVENTION

Hereinafter, embodiments of the present invention will be described in detail with reference to the accompanying drawings.

### First Embodiment

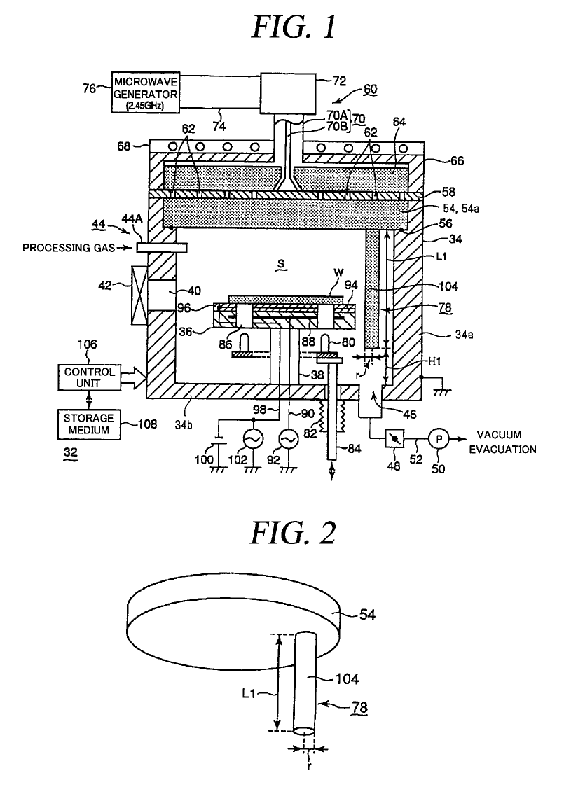

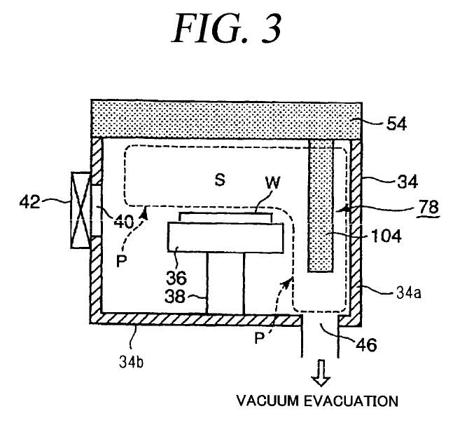

FIG. 1 illustrates a configuration view of a plasma processing apparatus in accordance with a first embodiment of the present invention; FIG. 2 provides a perspective view of a ceiling plate and a film deposition preventing member; and FIG. 3 shows a schematic diagram for illustrating a plasma generation state in a processing chamber.

As illustrated, a plasma processing apparatus 32 includes a cylindrical processing chamber 34 made of a conductor such as aluminum or the like, and the inside of the processing chamber 34 is configured as a sealed processing space S having, for example, a circular shape, wherein plasma is generated in the processing space S. The processing chamber 34 is grounded.

Further, the processing chamber 34 includes an opened ceiling portion 54a, a sidewall 34a and a bottom portion 34b, wherein the sidewall 34a and the bottom portion 34b are made of a conductor such as aluminum or the like.

Disposed in the processing chamber 34 is a mounting table 36 for mounting a target object, e.g., a semiconductor wafer W on the top surface thereof. The mounting table 36 is made of, e.g., alumite-treated aluminum or the like and formed in a substantially flat circular plate shape. The mounting table 36 is installed upright from the bottom portion 34b of the processing chamber 34 via a supporting column 38 made of, e.g., aluminum or the like.

Provided in the sidewall 34a of the processing chamber 34 is a loading/unloading opening 40 for target object, which is used for loading and unloading the wafer to and from the inside of the processing chamber 34, and a gate valve 42 for airtightly opening and closing the opening 40 is installed at the opening 40.

Furthermore, installed in the sidewall 34a of the processing chamber 34 is a gas introduction mechanism 44 for introducing a necessary processing gas into the processing chamber 34. Here, the gas introduction mechanism 44 includes, for example, a gas nozzle 44A formed through the sidewall 34a of the processing chamber 34, and the processing gas can be supplied from the gas nozzle 44A when necessary while its flow rate is being controlled. Also, it is possible to provide more than one gas nozzle 44A to introduce different kinds of gases or to install the nozzles in the ceiling portion of the processing chamber 34 in a showerhead shape.

Furthermore, in the bottom portion 34b of the processing chamber 34, there is provided a gas exhaust port 46 having a diameter of, e.g., about 2 to 15 cm. The gas exhaust port 46 is connected with a gas exhaust path 52 in which a pressure control valve 48 and a vacuum pump 50 are installed in sequence. With this configuration, the inside of the processing chamber 34 can be evacuated to a specific vacuum level as necessary.

Further, the ceiling portion 54a of the processing chamber 34 is opened, and a microwave transmissive ceiling plate 54 made of a dielectric material such as quartz or Al₂O₃ is installed airtightly at the ceiling portion 54a via a sealing member 56 such as an O ring. The thickness of the ceiling plate 54 is set to be, e.g., about 20 mm in consideration of its pressure resistance.

Furthermore, a planar antenna member 58 for introducing microwaves into the processing chamber 34 is mounted on the top surface of the ceiling plate 54 and connected to a microwave introduction mechanism 60 for supplying the microwaves to the planar antenna member 58. To be specific, in case of corresponding to a wafer having a size of about 300 mm, the planar antenna member 58 is formed of a circular plate made of a conductive material such as a silver-coated copper plate or an aluminum circular plate having a diameter of about 400 to 500 mm and a thickness of about 1 to several mm. The circular plate is provided with a plurality of microwave radiation holes 62 formed of through holes having, for example, an elongated groove shape. An arrangement pattern of the microwave radiation holes 62 is not particularly limited. For instance, they can be arranged in a concentric, spiral or radial pattern or can be uniformly distributed over the entire surface of the antenna member. The planar antenna member 58 has an antenna structure of a so-called RLSA (Radial Line Slot Antenna) type, which makes it possible to obtain a high-density plasma and a low electron energy.

Furthermore, a slow-wave member 64 made of, for example, aluminum nitride or the like is installed on the planar antenna member 58, and the slow-wave member 64 has a high-permittivity property to shorten the wavelength of the microwave. An entire surface of a top portion of the slow-wave member 64 is enclosed by a waveguide box 66 configured as a conductive vessel of a hollow cylindrical shape. The planar antenna member 58 is configured as a bottom plate of the waveguide box 66 and installed to face the mounting table 36 within the processing chamber 34. Provided on the top surface of the waveguide box 66 is a cooling jacket 68 for cooling the waveguide box 66 by flowing a coolant.

The peripheral portions of the waveguide box 66 and the planar antenna member 58 are electrically connected with the processing chamber 34. Further, the microwave introduction mechanism 60 has a coaxial waveguide 70 connected with the planar antenna member 58. Specifically, an outer conductor 70A of the coaxial waveguide 70 is connected to the center of the top portion of the waveguide box 66, and an inner conductor 70B of the coaxial waveguide 70 is connected to the center portion of the planar antenna member 58 through a hole formed through the center of the slow-wave member 64, wherein the outer conductor 70A has a circular cross section. Furthermore, the coaxial waveguide 70 is connected to a microwave generator 76 for generating microwaves of, e.g., about 2.45 GHz via a mode converter 72, a rectangular-shaped waveguide 74 and a matching box (not shown), and serves to propagate the microwaves to the planar antenna member 58.

The frequency of the microwaves is not limited to about 2.45 GHz and it is possible to use another frequency, e.g., about 8.35 GHz. Further, provided at the ceiling plate 54 on the bottom surface side of the planar antenna member 58 is a film deposition preventing member 78 made of a dielectric material and elongated from the ceiling plate 54 to correspond to a portion on which an unnecessary adhesion film is likely to be deposited.

Furthermore, provided under the mounting table 36 are plural, e.g., three lifter pins 80 (only two are illustrated in FIG. 1) for lifting a wafer W up and down while the wafer W is loaded or unloaded. The lifter pins 80 are lifted up and down by an elevation rod 84 which is installed to penetrate the bottom portion of the chamber via an extensible/contractible bellows 82. Further, provided in the mounting table 36 are pin insertion holes 86 for allowing the lifter pins 82 to be inserted therethrough. The entire mounting table 36 is made of a heat resistant material, for example, ceramic such as alumina or the like, and a heating element 88 is embedded in the ceramic. The heating element 88 is formed of, e.g., a thin plate-shaped resistance heater buried in almost the entire area of the mounting table 36 and connected to a heater power supply 92 via a wiring 90 which is extended through inside of the supporting column 38.

Furthermore, provided on the top surface of the mounting table 36 is a thin electrostatic chuck 96 in which a conductor line 94 is embedded in, e.g., a mesh shape. The wafer W placed on the mounting table 36, specifically, on the electrostatic chuck 96 is attracted to and held on the electrostatic chuck 96 by an electrostatic attracting force. The conductor line 94 of the electrostatic chuck 96 is connected to a DC power supply 100 via a wiring 98 to exert the electrostatic attracting force. Further, the wiring 98 is connected to a high frequency bias power supply 102 for applying a high frequency bias power of about 13.56 MHz to the conductor line 94 of the electrostatic chuck 96 when necessary. Further, depending on the types of processes, the high frequency bias power supply 102 may not be provided.

Hereinafter, the film deposition preventing member 78 formed at the ceiling plate 54 will be explained. The film deposition preventing member 78 is provided to prevent an unnecessary adhesion film from being deposited around the gas exhaust port 46 installed in the bottom portion 34b of the processing chamber 34. Specifically, as illustrated in FIG. 2, the film deposition preventing member 78 is configured as a rod-shaped member 104 which is formed in a rod shape by using a dielectric material. The rod-shaped member 104 is formed in, e.g., a columnar shape and the top portion thereof is bonded to the bottom surface of the ceiling plate 54 by welding or the like. Further, the rod-shaped member 104 is elongated down toward substantially the center of the gas exhaust port 46, and the microwaves are propagated to the rod-shaped member 104 from the ceiling plate 54, so that the plasma is also generated around the rod-shaped member 104.

In this case, the rod-shaped member 104 can be made of a dielectric material such as quartz or a ceramic material, e.g., alumina (Al₂O₃), aluminum nitride (AlN) or the like, but it is desirable to use the same material as that of the ceiling plate 54 in consideration of bonding strength with the ceiling plate 54, the propagation efficiency of the microwaves, and the like. A length L1 of the rod-shaped member 104 (see FIG. 1) is set to, e.g., about 5 to 30 cm, though it varies depending on the height of the processing chamber 34.

In this configuration, it is desirable to set a distance H1 between the lower end of the rod-shaped member 104 and the gas exhaust port 46 (see FIG. 1) to be not greater than about 100 mm in order to achieve a sufficient film deposition preventing effect, though it also varies depending on the power of the supplied microwaves, a process pressure or the like. If the distance H1 is greater than about 100 mm, the plasma is not sufficiently generated around the gas exhaust port 46 and therefore it is not possible to sufficiently achieve the film deposition preventing effect around the gas exhaust port 46. Furthermore, when the gas exhaust port 46 is formed in the sidewall 34a of the processing chamber 34, instead of in the bottom portion 34b, the distance between the lower end of the rod-shaped member 104 and the gas exhaust port 46 is also set to be not greater than about 100 mm, desirably.

Furthermore, a radius r of the rod-shaped member 104 (see FIG. 1) is desirably set to satisfy the formula “r≧λ/3.41” in order to allow the microwaves in a TM mode to be propagated efficiently. Here, λ stands for a wavelength of a microwave in the dielectric material constituting the rod-shaped member 104. By satisfying the above-mentioned formula, it is possible to efficiently propagate the microwaves in a certain propagation mode, e.g., the TM mode.

Furthermore, the lower end portion of the rod-shaped member 104 should not be inserted into the gas exhaust port 46 because the insertion of the lower end portion into the gas exhaust port 46 would disturb a flow of an exhaust gas. Further, when locating the rod-shaped member 104 eccentrically with respect to the center of the gas exhaust port 46 in order to avoid interference between the rod-shaped member 104 and the mounting table 36, it is possible to bend the lower end portion of the rod-shaped member 104 toward the gas exhaust port 46 to locate it above the center of the gas exhaust port 46.

The whole operation of the plasma processing apparatus 32 having the above-described configuration is controlled by a control unit 106 including, for example, a microcomputer or the like, and a computer program for performing this operation is stored in a storage medium 108 such as a floppy disk, a CD (Compact Disc), a flash memory or the like. To be specific, according to instructions from the control unit 106, a control of supply or flow rates of each gas, a control of supply or power of microwaves or high frequency waves, a control of process temperature or process pressure, and so forth are performed.

Hereinafter, a processing method, which is performed by using the above-mentioned plasma processing apparatus 32, will be explained with reference to FIG. 3.

First, after the gate valve 42 is opened, a semiconductor wafer W is transferred into the processing chamber 34 by a transfer arm (not shown) through the loading/unloading opening 40, and is mounted on a mounting surface of the top surface of the mounting table 36 by lifting the lifter pin 80 up and down, and the wafer W is electrostatically attracted to the electrostatic chuck 96 to be held thereon. The wafer W is maintained at a specific process temperature by the heating element 88 when necessary. While controlling the flow rate of a gas supplied from a non-illustrated gas source, the gas is supplied into the processing chamber 34 through the gas nozzle 44A of the gas introduction mechanism 44, and by controlling the pressure control valve 48, the inside the processing chamber 34 is maintained at a specific process pressure level.

At the same time, the microwave generator 76 of the microwave introduction mechanism 60 is operated. As a result, the microwaves generated from the microwave generator 76 are provided to the planar antenna member 58 via the rectangular-shaped waveguide 74, the coaxial waveguide 70 and the slow-wave member 64. The microwaves whose wavelengths are shortened by the slow-wave member 64 are transmitted through the ceiling plate 54 and introduced into the processing space S, and thereby plasma is generated in the processing space S and a desired plasma process is operated.

Here, plasma P is generated mainly in the processing space S existing between the ceiling plate 54 and the mounting table 36 by the microwaves transmitted or propagated through the ceiling plate 54. In the present disclosure, since the rod-shaped member 104 made of the dielectric material is elongated downward from the ceiling plate 54 toward the gas exhaust port 46 to serve as the film deposition preventing member 78, and the lower end portion of the rod-shaped member 104 is located around the gas exhaust port 46, the microwaves propagated through the ceiling plate 54 are also propagated to the rod-shaped member 104 made of the dielectric material. Accordingly, as illustrated in FIG. 3, plasma P is generated not only in the processing space S but also in a peripheral space around the rod-shaped member 104.

In comparison, in the conventional plasma processing apparatus, for example, the remaining active species or dissociated gases concentrated to the gas exhaust port together with the exhaust gas are deactivated around the gas exhaust port and then deposited as the unnecessary adhesion film thereat. However, in accordance with the present disclosure, as mentioned above, plasma is also generated around the gas exhaust port 46. Thus, deposition of the unnecessary adhesion film around the gas exhaust port 46 can be prevented because energy is supplied thereto by the plasma generated in that region. Accordingly, generation of particles caused by the unnecessary adhesion film can be prevented. Further, it is also possible to prevent the gas exhaust path from being narrowed as a result of being clogged with the unnecessary adhesion film. Meanwhile, FIG. 3 mainly shows components necessary to explain the present invention, while omitting other components.

In addition, the radius r of the rod-shaped member 104 is set to satisfy the formula “r≧λ/3.41” (λ is a wavelength of a microwave propagating in the rod-shaped member 104) in order to allow the microwaves in the TM mode to be propagated efficiently. Also, the above-mentioned formula can be easily obtained by applying Maxwell's equation to the microwave transmission line.

Here, the shape of the rod-shaped member 104 is not limited to the cylindrical shape having the circular cross section, but the rod-shaped member 104 can be of a shape having a triangular or any other polygonal cross section.

In particular, as for a rod-shaped member 104 having a rectangular cross section, a length a of a longer side of the rectangular cross section (as for a square, a length of one side) is set to satisfy the formula, “a≧λ/2” (λ is a wavelength of a microwave propagating in the rod-shaped member 104), so that the microwaves in a TE mode can be propagated efficiently.

### Evaluation of First Embodiment

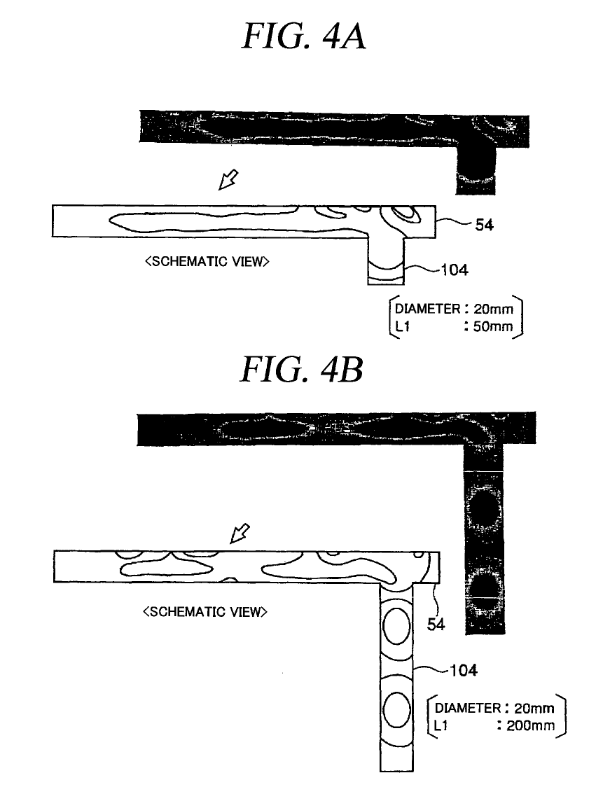

A simulation was conducted for the first embodiment of the present invention using the film deposition preventing member 78, so that microwave propagation was evaluated. Hereinafter, the result of the evaluation will be explained. FIGS. 4A and 4B provide photographs showing the results of the simulation using the rod-shaped (columnar) film deposition preventing member having the circular cross section in accordance with the first embodiment of the present invention. Further, each photograph is provided together with a schematic diagram for the convenience of explanation. In this example, both the ceiling plate 54 and the rod-shaped member 104 are made of quartz, and the diameter of the ceiling plate 54 is set to be about 400 mm while the diameter (2×r) of the rod-shaped member 104 is set to be about 20 mm. Furthermore, the length L1 of the rod-shaped member 104 is set to be about 50 mm in FIG. 4A and about 200 mm in FIG. 4B. The patterns shown in these drawings represent distribution of electrical fields of microwaves. As can be seen from FIGS. 4A and 4B, regardless of the length of the rod-shaped member 104, electrical fields of the microwaves are detected not only in the ceiling plate 54 but also in both rod-shaped members 104. Therefore, it can be confirmed that the microwaves are propagated sufficiently through both rod-shaped members 104 and thus the plasma can be generated around these rod-shaped members 104.

### Second Embodiment

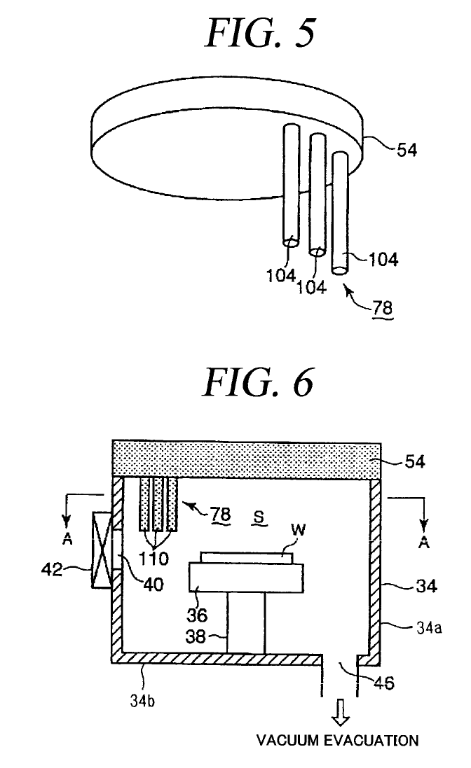

Hereinafter, a plasma processing apparatus in accordance with a second embodiment of the present invention will be explained. FIG. 5 illustrates a perspective view showing a ceiling plate and a film deposition preventing member 78 used in the plasma processing apparatus in accordance with the second embodiment of the present invention.

In the foregoing first embodiment, one rod-shaped member 104 is used as the film deposition preventing member 78, but in this second embodiment, a plurality of, for example, three rod-shaped members 104 are used. In this case, as the number of the rod-shaped member 104 increases, the amount of plasma generated around them can also be increased.

### Third Embodiment

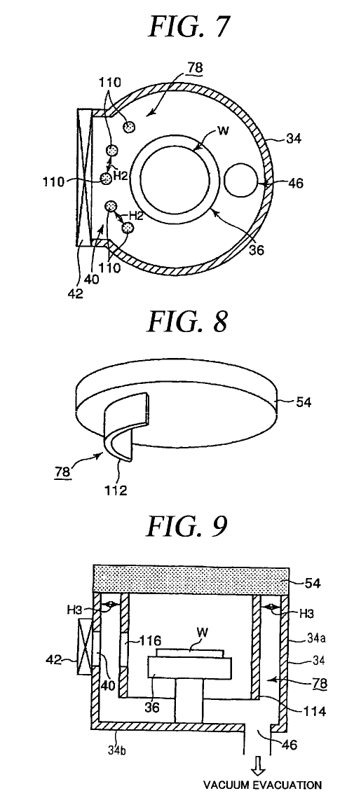

Hereinafter, a plasma processing apparatus in accordance with a third embodiment of the present invention will be explained. FIG. 6 provides a schematic configuration view of the plasma processing apparatus in accordance with the third embodiment of the present invention; and FIG. 7 provides a cross-sectional view taken in the direction of the arrows along the line A-A in FIG. 6, wherein these figures mainly show components necessary to explain the present invention, while omitting other components for the simplicity of explanation. In FIGS. 6 and 7, components identical with those described in FIG. 1 will be assigned like reference numerals.

In the foregoing first and second embodiments, the vicinity of the gas exhaust port 46 is exemplified as a portion on which an unnecessary adhesion film is deposited easily, but the portion where the unnecessary adhesion film is easily deposited is not limited to this example. Depending on the types of plasma processes, an example portion where the unnecessary adhesion film is easily deposited can be the opening 40 for loading and unloading the target object.

Since the opening 40 and the gate valve 42 are provided, a thermal condition of this opening 40 portion is different from that of the rest part of the sidewall 34a, so that the unnecessary adhesion film tends to be deposited at this portion easily. Here, in the third embodiment, provided as a film deposition preventing member 78 are a plurality of dielectric rod-shaped members 110 having the same structure as that described in the first and second embodiments, wherein the plurality of rod-shaped members 110 are elongated downward from a ceiling plate 54, as illustrated in FIGS. 6 and 7. In this embodiment, five rod-shaped members 110 are arranged at a preset interval along the lengthwise direction of the opening 40.

Here, the length of each rod-shaped member 110 is set to be short in order to prevent collision and interference between the rod-shaped members 110 and the wafer W which is loaded or unloaded through the opening 40. Furthermore, distances between lower end portions of the rod-shaped members 110 and the opening 40 are set to be, desirably, not greater than about 100 mm in order to obtain a film deposition preventing effect on this portion. The setting of distance is the same as that of the first and second embodiments. Likewise, if an interval H2 between the rod-shaped members 110 is set to be, desirably, not greater than about 100 mm, plasma can be generated between these rod-shaped members 110 themselves, so that it is possible to exert a sufficient film deposition preventing effect.

In accordance with the third embodiment, since the plasma is generated around each rod-shaped member 110, deposition of an unnecessary adhesion film around the opening 40 for loading and unloading the target object can be prevented.

In addition, it is possible to combine the configuration of the third embodiment with those of the first and second embodiments in order to prevent the deposition of the unnecessary adhesion film around the gas exhaust port 46 and the opening 40.

### Fourth Embodiment

Hereinafter, a plasma processing apparatus in accordance with a fourth embodiment of the present invention will be explained. FIG. 8 illustrates a perspective view showing a ceiling plate and a film deposition preventing member used in the plasma processing apparatus in accordance with the fourth embodiment.

In the foregoing third embodiment illustrated in FIGS. 6 and 7, provided as the film deposition preventing member 78 are the plurality of rod-shaped members 110 which are arranged along the opening 40, but it is also possible to install a plate-shaped member 112 made of a dielectric material along the opening 40. In this case, it is desirable to form the plate-shaped member 112 in a circular arc shape conforming to the shape of the opening 40. With this configuration, it is possible to obtain the same effects as obtained by the third embodiment.

### Fifth Embodiment

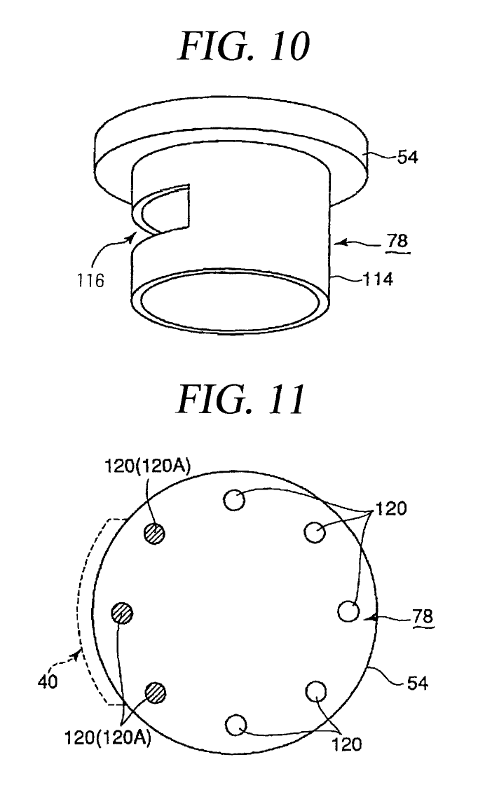

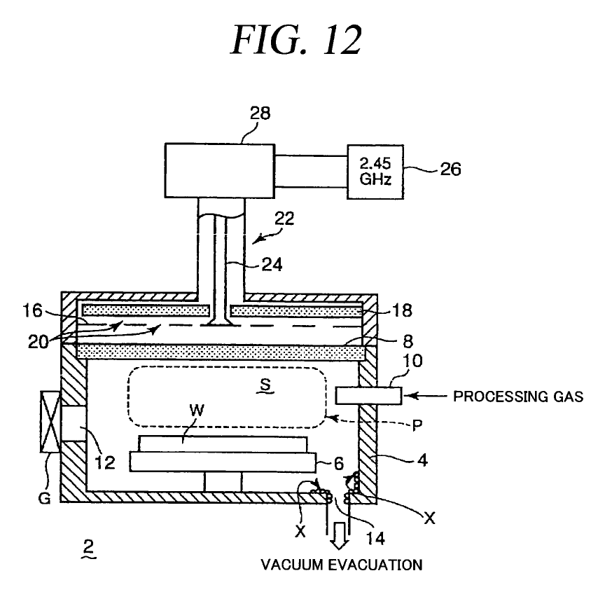

Hereinafter, a plasma processing apparatus in accordance with a fifth embodiment of the present invention will be explained. FIG. 9 provides a schematic configuration view of the plasma processing apparatus in accordance with the fifth embodiment of the present invention; and FIG. 10 illustrates a perspective view showing a ceiling plate and a film deposition preventing member used in the plasma processing apparatus in accordance with the fifth embodiment.

The foregoing first to fourth embodiments have been described for the case of preventing an unnecessary adhesion film from being deposited around a gas exhaust port 46 or an opening 40, but depending on plasma processes, the entire inner sidewall surface of the processing chamber can be a portion on which the unnecessary adhesion film is deposited easily. In such case, as illustrated in FIGS. 9 and 10, a cylindrical member 114 made of a dielectric material is installed along the inner sidewall of the processing chamber 34 in a circular ring shape (cylindrical shape) as a film deposition preventing member 78. The upper end of the cylindrical member 114 is thermally bonded to the ceiling plate 54, and the cylindrical member 114 is installed to surround the mounting table 36.

Further, provided at a portion of the cylindrical member 114 corresponding to the opening 40 is a horizontally elongated opening 116 for allowing a wafer W to pass therethrough. Here, a distance H3 between a sidewall 34a of the processing chamber 34 and the cylindrical member 114 is set to be, desirably, not greater than about 100 mm in order to obtain a film deposition preventing effect on the sidewall 34a of the processing chamber 34.

In accordance with the fifth embodiment, since plasma is generated around the cylindrical member 114, it is possible to prevent an unnecessary adhesion film from being deposited on the sidewall of the chamber including the vicinity of the opening 40. Further, if the length of the cylindrical member 114 is set to be long and the distance between the lower end portion thereof and the gas exhaust port 46 is set to be, desirably, within about 100 mm, it is also possible to prevent deposition of the unnecessary adhesion film around the gas exhaust port 46.

### Sixth Embodiment

In the foregoing fifth embodiment, the cylindrical member 114 made of the dielectric material is provided as the film deposition preventing member 78, but it may be also desirable to install the rod-shaped member made of the dielectric material as described in the foregoing embodiments, instead of the cylindrical member 114. FIG. 11 provides a bottom view showing a ceiling plate and a film deposition preventing member used in the plasma processing apparatus in accordance with the sixth embodiment of the present invention. As illustrated in FIG. 11, a plurality of rod-shaped members 120 made of a dielectric material elongated downward from a ceiling plate 54 is arranged at a preset interval along a sidewall 34a of a processing chamber 34 in a ring shape. Here, the distance between the rod-shaped members 120 themselves and the distance between the rod-shaped member 120 and the sidewall 34a are set to be, desirably, not greater than about 100 mm. Further, the length of a rod-shaped member 120A corresponding to a opening 40 for loading and unloading the target object is set to be short so as not to interfere with a wafer W which is loaded and unloaded.

In this sixth embodiment, it is possible to obtain the same effects as obtained by the foregoing fifth embodiment described with reference to FIGS. 9 and 10.

Furthermore, the present disclosure can be applied to various plasma processes such as a film forming process, a plasma etching process, a plasma ashing process and the like.

In addition, the target object to be processed is not limited to the semiconductor wafer, but the present invention can be applied to plasma processing of a glass substrate, a ceramic substrate, a rectangular LCD (Liquid Crystal Display) substrate and the like.

What is claimed is:

1. A plasma processing apparatus comprising:
a processing chamber having an opened ceiling portion, a sidewall and a bottom portion, and capable of being evacuated to a vacuum therein;
a mounting table installed in the processing chamber, for mounting thereon a target object to be processed;
a ceiling plate airtightly installed at the ceiling portion and made of a microwave-transmissive dielectric material;
a planar antenna member installed on a top surface of the ceiling plate, for introducing a microwave into the processing chamber;
a microwave supply mechanism for supplying the microwave to the planar antenna member; and
a gas introduction mechanism for introducing a necessary processing gas into the processing chamber,
wherein a film deposition preventing member made of a dielectric material and elongated from the ceiling plate is installed to correspond to a portion where an unnecessary adhesion film is likely to be deposited within the processing chamber.

2. The plasma processing apparatus of claim 1, wherein the sidewall or the bottom portion of the processing chamber is provided with a gas exhaust port, and
the portion where the unnecessary adhesion film is likely to be deposited is the vicinity of the gas exhaust port of the processing chamber, and the film deposition preventing member is configured as a rod-shaped member formed in a rod shape.

3. The plasma processing apparatus of claim 2, wherein a distance between a lower end portion of the rod-shaped member and the gas exhaust port is not greater than about 100 mm.

4. The plasma processing apparatus of claim 2, wherein the rod-shaped member is formed in a columnar shape and a radius r of the rod-shaped member of the columnar shape satisfies a formula of r≧λ/3.41 (λ represents a wavelength of a microwave in the dielectric material constituting the rod-shaped member).

5. The plasma processing apparatus of claim 2, wherein the rod-shaped member has a cross section formed in a rectangular shape and a length a of a longer side of the rectangular cross section satisfies a formula of a≧λ/2 (λ represents a wavelength of a microwave in the dielectric material constituting the rod-shaped member).

6. The plasma processing apparatus of claim 1, wherein the portion where the unnecessary adhesion film is likely to be deposited is the sidewall of the processing chamber, and the film deposition preventing member is formed to conform to the shape of the sidewall.

7. The plasma processing apparatus of claim 6, wherein an opening for loading and unloading the target object is provided in the sidewall of the processing chamber, and
the portion where the unnecessary adhesion film is likely to be deposited is the opening for loading and unloading the target object formed in the processing chamber.

8. The plasma processing apparatus of claim 6, wherein the film deposition preventing member is configured as a plurality of rod-shaped members arranged along the sidewall while spaced apart from the sidewall by a predetermined interval.

9. The plasma processing apparatus of claim 6, wherein the film deposition preventing member is configured as a plate-shaped member formed along the sidewall of the processing chamber.

10. The plasma processing apparatus of claim 9, wherein the plate-shaped member has a cross section formed in a circular arc shape.

11. The plasma processing apparatus of claim 6, wherein the film deposition preventing member is configured as a cylindrical member formed along the sidewall of the processing chamber.

12. The plasma processing apparatus of claim 6, wherein a distance between the film deposition preventing member and the sidewall of the processing chamber is not greater than about 100 mm.

13. The plasma processing apparatus of claim 8, wherein the rod-shaped member is formed in a columnar shape and a radius r of the rod-shaped member of the columnar shape satisfies a formula of r≧λ/3.41 (λ represents a wavelength of a microwave in the dielectric material constituting the rod-shaped member).

14. The plasma processing apparatus of claim 8, wherein the rod-shaped member has a cross section formed in a rectangular shape and a length a of a longer side of the rectangular cross section satisfies a formula of a≧λ/2 (λ represents a wavelength of a microwave in the dielectric material constituting the rod-shaped member).
